(19) United States
(12) Patent Application Publication
(10) Pub. No.: US 2023/0305590 A1
(43) Pub. Date: Sep. 28, 2023

(54) A DATA PROCESSING METHOD

(71) Applicant: UNIVERSITY OF SOUTH AUSTRALIA, Adelaide (AU)

(72) Inventors: Russell Brinkworth, Woodcroft (AU); Anthony Finn, Carey Gully (AU); Daniel Griffiths, Mawson Lakes (AU); Phillip Stanley Martin Skelton, Craigmore (AU)

(21) Appl. No.: 18/011,003

(22) PCT Filed: Mar. 11, 2021
(86) PCT No.: PCT/AU2021/050213

§ 371 Date: Dec. 16, 2022

(30) Foreign Application Priority Data
Mar. 13, 2020 (AU) 2020900764

(51) Int. Cl. G06F 1/02; G06F 11/00; G16Z 99/00

(52) U.S. Cl. CPC G06F 1/022; G06F 11/002; G16Z 99/00

(57) ABSTRACT

A computer-implemented data processing method to improve information quality in data sequences by attenuating noise in the data sequences, the method including: receiving input data sequences, having a plurality of elements, from one or more sensors, each of the elements having at least one dimensional component; performing a spectral analysis on the dimensional component of each of the elements, independently, to estimate a signal profile of the input data sequences; estimating a noise profile of the input data sequences using calibration data associated with the sensor; dynamically calculating a time-constant for a noise attenuation filter, and adapting the time-constant over time, for each one of the elements in the input data sequences, based on the relationship between the noise profile and the signal profile; applying the noise attenuation filter for each one of the elements to each one of the elements, respectively, to filter the input data sequences to derive filtered data sequences; and outputting the filtered data sequences.

### PRIORITY CLAIM

This application is a national stage application of PCT/AU2021/050213, filed on Mar. 11, 2021, which claims the benefit of and priority to Australian Patent Application No. 2020900764, filed on Mar. 13, 2020, the entire contents of which are each incorporated by reference herein.

### TECHNICAL FIELD

The present disclosure relates to a computer-implemented data processing method to improve information quality in data sequences by attenuating noise in the data sequences. In particular, the method includes the steps of dynamically calculating a time-constant for a noise attenuation filter, and adapting the time-constant over time, for each element in inputted data sequences based on a relationship between the noise profile and the signal profile of the inputted data sequences, and applying the noise attenuation filter to each one of the elements, respectively, to filter the inputted data sequences to derive filtered data sequences.

In particular, but not exclusively, the data processing method is a pre-processing technique to improve information quality in data sequences so that relatively more useful information can later be extracted from filtered data sequences.

### BACKGROUND

Digital data processing techniques, in particular digital pre-processing techniques, to improve information quality in, and/or reduce dynamic range of, data sequences are typically pre-determined and application specific. For example, for noisy or cluttered image or speech data, pre-processing techniques may be used to improve the signal-to-noise ratio of the image or speech data before further image processing or speech recognition techniques are to be performed. It is also possible for the range of the incoming data to be non-linearly encoded in order to make better use of the available bandwidth. One example of a pre-processing method for image data is gamma correction, and A-Law and □-Law are examples of dynamic range compression for audio signals. Gamma correction is used to optimise information quality in image data by applying a gamma correction function having a set gamma level for the image data. In respect of an image data sequence, however, a set gamma level may not be appropriate for the image data over time. Further, a set gamma level may not be appropriate for each pixel of an image data sequence.

Certain digital data processing techniques for improving information quality in data sequences that have pre-determined settings, such as the above-mentioned gamma correction, therefore have significant drawbacks. There is therefore a need to provide an improved data processing method to improve information quality in data sequences.

The above discussion of background art is included to explain the context of the present disclosure. It is not to be taken as an admission that any of the documents or other material referred to was published, known or part of the common general knowledge at the priority date of any one of the claims of this specification.

### SUMMARY

According to one aspect of the present disclosure, there is provided a computer-implemented data processing method to improve information quality in data sequences by attenuating noise in the data sequences, the method including: receiving input data sequences, having a plurality of elements, from one or more sensors, each of the elements having at least one dimensional component; performing a spectral analysis on the dimensional component of each of the elements, independently, to estimate a signal profile of the input data sequences; estimating a noise profile of the input data sequences using calibration data associated with the sensor; dynamically calculating a time-constant for a noise attenuation filter, and adapting the time-constant over time, for each one of the elements in the input data sequences, based on the relationship between the noise profile and the signal profile; applying the noise attenuation filter for each one of the elements to each one of the elements, respectively, to filter the input data sequences to derive filtered data sequences; and outputting the filtered data sequences.

In one embodiment, the at least one dimensional component includes a temporal component. In another embodiment, the at least one dimensional component includes a temporal component derived from the at least one dimensional component. The at least one dimensional component may further include a spatial component. In this embodiment, the temporal component may be derived from the spatial component. That is, for example, each of the elements may have a spatial component that can be animated such that it appears as if it had a temporal component. The spatial component may be animated such that, at each time step, components of the incoming data are observed by different elements. One example of this is moving the data past each element in a scanning motion. Another example is to perform pseudo-random movements of the data over the elements.

In an example, the input data sequences are video data, of any modality, and the elements include pixels. The sensors in this example may be an array of image sensors (e.g., visible, infra-red, or multispectral). In another example, the elements include colour and or wavelength channels. In yet another example, the input data sequences are audio data, of any modality, and the elements include spectrograms or frequency bands derived from the audio data. The method improves information quality in these data sequences by attenuating noise in the data sequences and by simultaneously improving bandwidth utilisation of the outputted filtered data sequences.

In certain, non-exclusive embodiments, the noise attenuation filter includes a low-pass filter having said time-constant. Thus, the low-pass filter is adaptive and possibly different for each element. The application of the low-pass filter improves signal quality by attenuating noise in the data sequences over time.

In another embodiment, the method further includes estimating a signal-to-noise ratio (SNR) of the input data sequences based on the relationship between the noise profile and the signal profile.

In another embodiment, the method further includes comparing the SNR to a minimum target SNR and calculating the time-constant based on a result of the comparison of the SNR and the minimum target SNR.

The SNR is then compared to the minimum target SNR by dividing the SNR by the minimum target SNR to obtain a filter value and calculating the time-constant is based on the filter value, such that a relatively small filter value results in little or no filtering and a relatively large filter value results in increasing amounts of filtering proportional to the filter value. The time-constant further has a maximum time-constant limit corresponding to a threshold filter value.

Additionally, the method further includes dynamically calculating a further time-constant for a further filter, for filtering the time-constant for the noise attenuation filter, based on trend of the SNR over time, and applying the further filter to smooth the time-constant over time. That is, if the trend of the SNR over time is increasing, the further time-constant is decreased, and, if the trend of the SNR over time is decreasing, the further time-constant is increased. In certain embodiments, to minimize rapid changes and fluctuations, the further filter is also a low-pass filter having said further time-constant.

Filtering a data signal, including data sequences over time, allows or enables the attenuation of noise at frequency ranges where the signal power is less than that of the noise, effectively enhancing the quality of the data. Under-filtering a signal is functional but inefficient, taking more samples than required to produce an equivalent result or reducing the capacity to make correct decisions based on the data. Over-filtering will improve the signal quality as judged by static metrics but supress actual changes in the signal setpoint, reducing dynamic and high-frequency details in the signal and inducing error. In the vast majority of cases the power of the signal relative to the noise at different frequencies, and the dynamics of the signal itself, vary over time and across sensor elements. As a result, what the desirable filter parameters are changes over both these dimensions. This means independent adaptive filtering can produce substantially better results than fixed filters, if set intelligently.

In another embodiment, the method further includes dynamically compressing the dynamic range of the filtered data sequences by applying an input gain to the filtered data sequences to derive corrected filtered data sequences.

In another embodiment, the method further includes determining an adaptation level from the time-constant over time, and determining the input gain using the adaptation level, wherein the input gain is larger with lower adaptation levels and the input gain is smaller with higher adaptation levels.

In another embodiment, the method further includes estimating skewness of the input data sequences by determining an amplitude modulation of the adaptation level across the input data sequences over time and determining magnitude of the input gain based on the skewness.

In another embodiment, the method further includes scaling the magnitude of the input gain between a minimum input gain and a maximum input gain.

In another embodiment, the method further includes dynamically compressing the corrected filtered data sequences by applying dynamic gamma correction, having a gamma correction factor, to the corrected filtered data sequences to derive compressed filtered data sequences.

In another embodiment, the method further includes calculating the gamma correction factor based on the skewness of the incoming data.

In another embodiment, the method further includes dynamically compressing the compressed filtered data sequences by applying further dynamic gamma correction, having a further gamma correction factor, to the compressed filtered data sequences to derive further compressed filtered data sequences, wherein calculating the further gamma correction factor is also based on the skewness. That is, the above steps of dynamically compressing the filtered data sequences and the compressed filtered data sequences compress the dynamic range of the data signal while also enhancing dynamic elements and suppressing static ones.

In another embodiment, the method further includes scaling the compressed filtered data sequences to a designated bandwidth to derive output data sequences by applying a designated gain based on a historical midpoint value of bandwidth usage of the compressed filtered data sequences That is, the method scales the data signal to a known range or bandwidth. In an example, the historical midpoint value is taken across the entire array of sensor data, as seen as input to this scaling step.

In another embodiment, the method further applies a further non-linear correction to the data signal based on the estimated incoming signal distribution (skewness).

### BRIEF DESCRIPTION OF DRAWINGS

Embodiments of the present disclosure will now be described, by way of example only, with reference to the accompanying drawings, in which:

FIG. 1 is a flow chart of a computer-implemented data processing method according to an embodiment of the present disclosure;

FIG. 2 is a block diagram of an embodiment of a system for implementing the method of FIG. 1;

FIG. 3 is part of a flow chart of a computer-implemented data processing method according to an embodiment of the present disclosure;

FIG. 4 is a further part of the flow chart of the embodiment of FIG. 2;

FIG. 5 is a further part of the flow chart of the embodiment of FIG. 2;

FIG. 6 is a further part of the flow chart of the embodiment of FIG. 2; and

FIG. 7 is a further part of the flow chart of the embodiment of FIG. 2.

### DETAILED DESCRIPTION

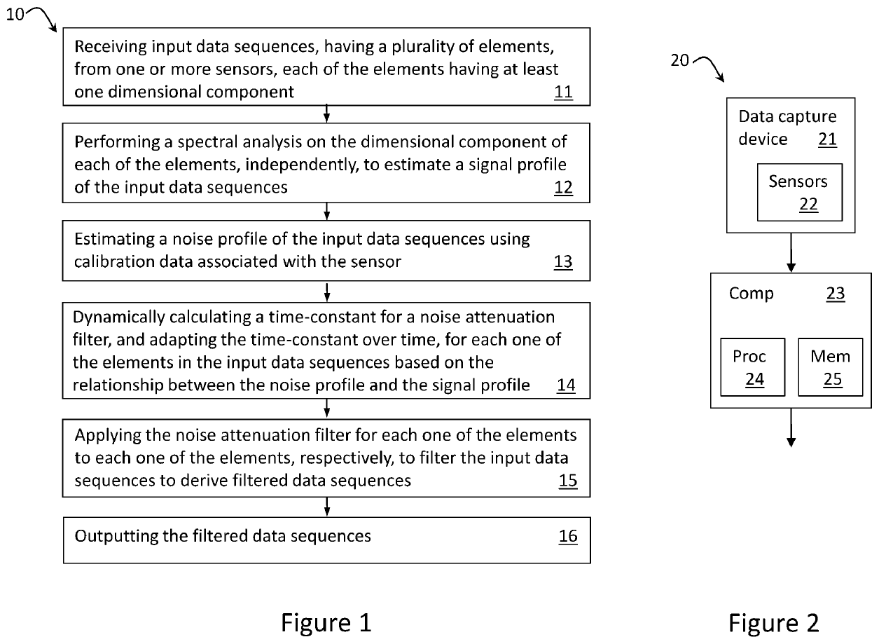

A flow chart summarising a computer-implemented data processing method 10 to improve information quality in data sequences by attenuating noise in, and compressing, the data sequences according to an embodiment of the present disclosure, is shown in FIG. 1. The method 10 includes: the steps of: receiving 11 input data sequences, having a plurality of elements, from one or more sensors, each of the elements having at least one dimensional component. That is, each of the elements have at least one degree of freedom, such as a temporal component or a spatial component.

The method 10 further includes performing 12 a spectral analysis on the dimensional component of each of the elements, independently, to estimate a signal profile of the input data sequences. In the embodiment, the dimensional component is the temporal component. The method 10 then includes: estimating 13 a noise profile of the input data sequences using calibration data associated with the sensor; dynamically calculating 14 a time-constant for a noise attenuation filter, and adapting the time-constant over time, for each one of the elements in the input data sequences, based on the relationship between the noise profile and the signal profile; applying 15 the noise attenuation filter for each one of the elements to each one of the elements, respectively, to filter the input data sequences to derive filtered data sequences; and outputting 16 the filtered data sequences.

FIG. 2 shows an embodiment of the computer-implemented method 10 being implemented by a computing system 20. The system 20 includes a data capture device 21, such as a camera or microphone, having one or more sensors 22 (for pixels or channels) configured to capture data sequences, such as image or sound data, and communicate the data sequences to a computer 23, having one or more processors 24, or processor types (e.g., CPU, GPU, GPGPU, FPGA, etc), configured to implementing the steps of the method 10, as input data sequences. The method 10 is embodied in software (e.g., program code) that is implemented by the processor(s) 24. Also, the software could be supplied in a number of ways to the system 20, such as on-board memory 25 or via data communication with the processor(s) 24. The system 20 thus performs the method 10 to output the filtered data sequences.

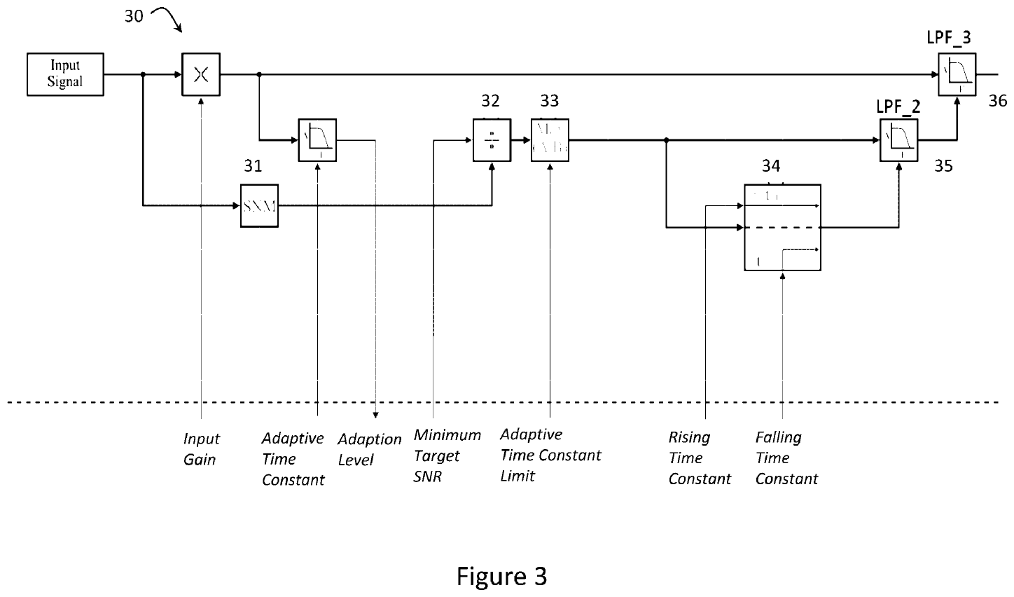

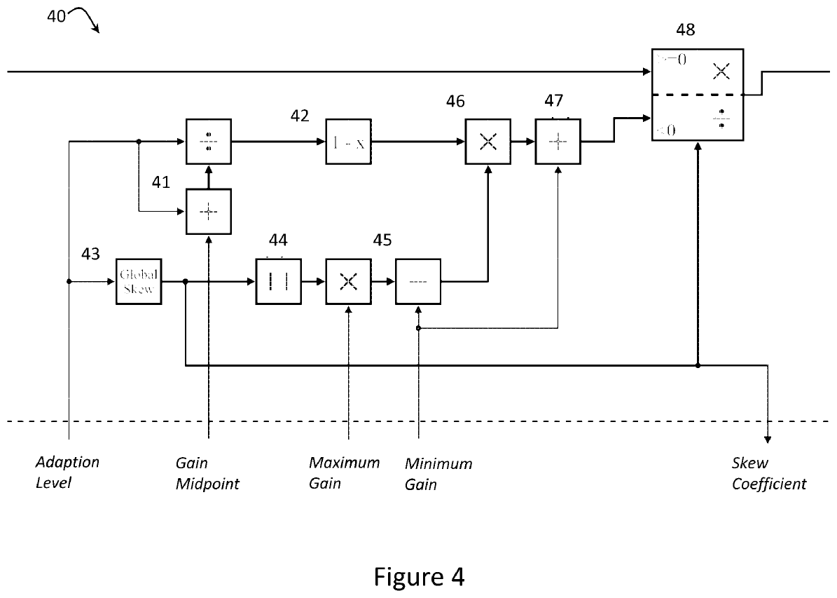

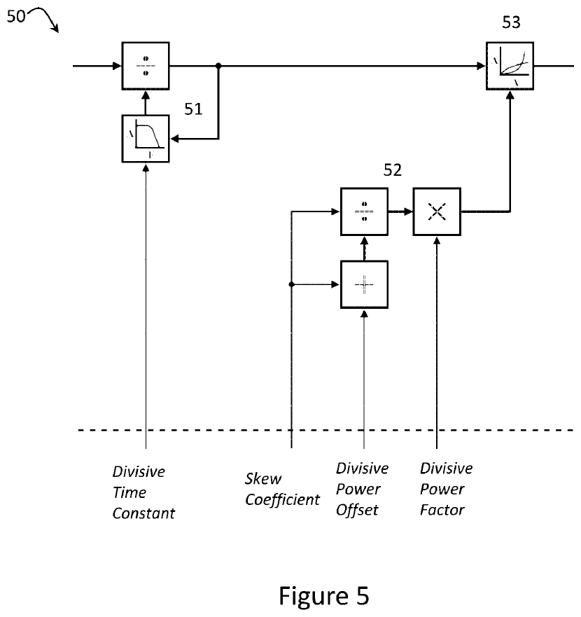

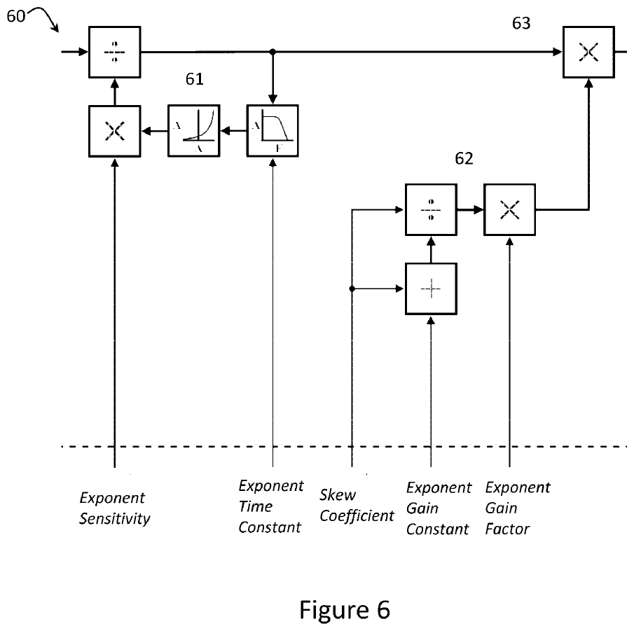

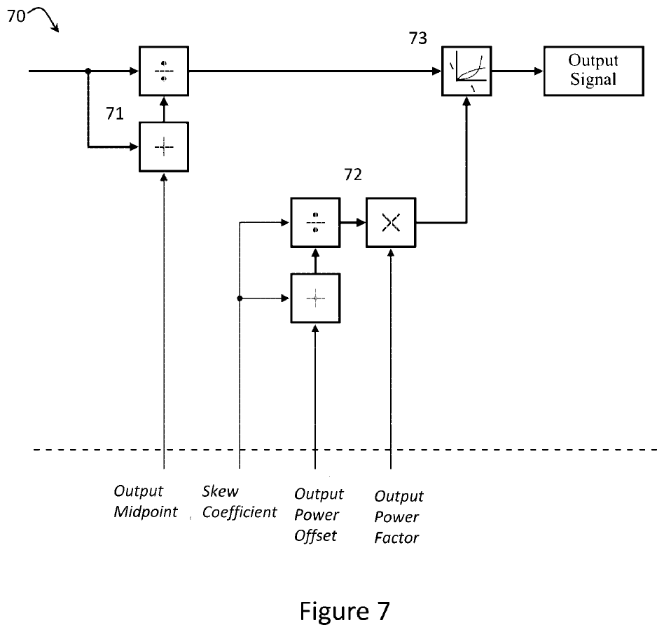

An embodiment of the method 10 will now be described with reference to FIGS. 3 to 7. In the embodiment, the input data sequences are video or image data, and the elements include pixels. The embodiment is an image processing model, which assumes that the incoming image data is real and positive. This constraint holds for both visual and (depending on scaling) infra-red images but may not be the case for other modalities (e.g., sound), which can equally be applied to the model. In cases where the incoming data does not fit this constraint, such as sound, the magnitude of the data is processed.

The model shown in FIGS. 3 to 7 has five steps, each shown in a separate figure. The model takes inputted image data sequences, applies the method 10, and outputs filtered data sequences having their noise components attenuated and bandwidth utilisation improved.

The first step 30 of the model is a per-element temporal filter, implemented as a low pass filter (LPF_3). A low pass filter is employed since the underlying information in the data typically has more power at low frequencies and the noise is typically white (equal at all frequencies). Thus, there is a frequency above which there is more noise than signal and suppressing the data at these frequencies will result in a relatively higher quality outcome. If this condition does not hold (i.e. there is more noise in a different frequency band) then this process can be realized by another class of filter (e.g., if there is more noise at low frequencies then a high pass filter can be utilized).

Nearly all the complexity in this step comes from the adaptive nature of the time constant controlling the filter LPF_3. Unlike certain prior uses of low pass filters, the model does not set have a set filter strength. Instead the model of the present disclosure dynamically calculates the most desirable filter time-constant on a per-sample basis. This philosophy is repeated throughout the model, using parameters to set the rate of adaptation and not the filter time constants themselves.

The first step 30 of the model includes a number of sub-steps to implement the per-element temporal filter. In sub-step 31, a sensor noise model (SNM) is used to map the incoming data value into a signal quality measurement, usually based on the signal-to-noise ratio (SNR). The formula for the SNM function is determined via sensor calibration data. The metric of interest (typically SNR) for all possible sensor values is estimated via experimentation. When Gaussian White Additive Noise is the dominant form of noise in the sensor, the resulting SNM function will have a positive slope, meaning larger sensor values are associated with relatively higher quality signals and hence less filtering is required.

In sub-step 32, the SNR of the current input signal (sensor reading) is compared to the Minimum Target SNR value by dividing the former by the latter. That is:
a. Small outputs from this function (i.e. when the signal is large compared the Minimum Target SNR) will result in little to no filtering, because the signal is already equal or greater than the desired signal quality; and
b. Large outputs from this function will cause increasing amounts of filtering, proportional to the disparity between the actual and desired signal quality.

In sub-step 33, a maximum operation limits the input value against the Adaptive Time Constant Limit to prevent over-filtering/blurring on especially low-quality data.

In sub-step 34, LPF_2 is used to limit the rate of adaptation in the time constant for LPF_3 and ensure a smooth response from the overall processing step. It is also needed to reduce blurring and ghosting artefacts when periods of relatively high signal quality are followed by periods of relatively low signal quality. Without an adaptive filter here the long time-constants associated with periods of relatively low signal quality would commence relatively too quickly, causing excessive bleed-over from the previous values; hence obscuring the new data.

In sub-step 35, the filter rate for LPF_2 is determined using the trend (slope or derivative) of incoming data over time. That is:
a. If the quality of the current input signal is better than the previous sample (i.e. it has a higher value from the SNM function), reduce the time constant for LPF_2. Thus, the LPF_2 adapts rapidly to the new operating point; thereby not continuing to filter more aggressively than the new values require; and
b. If the quality of the current input signal is worse than the previous sample, increase the time constant in LPF_2 and slow down adaptation; thereby not moving to relatively strong filtering too quickly which would cause excessive bleed over of the previous low noise (typically high amplitude) values into the new high noise (typically low amplitude) values.

This will ensure the model maintains the ability to encode relatively fast changes when entering a relatively lower quality operating point but will relatively slowly reduce this ability in the interest of improving overall signal quality (by attenuating high frequency noise).

In sub-step 36, the calculated time constant is then used to filter the incoming signal, giving a result derived from current and historical signal quality.

The model thus uses the properties of the incoming signal to autonomously modify the filtering. The model does so continuously, automatically and on a per-sample basis. The overall goal is to improve the SNR (signal quality) by reducing the frequency components of the sensor reading that contain a lower proportion of SNR than is desired. The SNR function is used to estimate the data quality at each sensor value. Using a target signal quality provided by the user, the model then automatically determines at what point in the spectrum (frequency) noise needs to be removed in order to achieve the desired signal quality and calculates the desired filter parameters to do this. Before this adaptive filtering is applied the filter parameters themselves are filtered to ensure transitions from high and low signal quality durations are maintained and sensor data are not filtered more than required.

The second step 40 of the model applies an adaptative non-linear gain to compress the dynamic range of the data. Using the Adaptation Level from the first step 30, the history of the signal is incorporated into the second step 40; thus applying different gains to historically low and high amplitude elements. If possible, and desired, the overall skewness of the data (Skew Coefficient) is used to control the magnitude of this adaptive non-linear gain. Highly skewed data requires larger differences between the maximum and minimum gains; whereas data with low skew passes this step with minimal variation in gain.

In sub-step 41, a Naka-Rushton function

$$( \frac{{x}^{n}}{{x}^{n} + {c}^{n}} )$$

is used where x is the Adaptation Level of the sample, n is the desired slope of the response over the parameter space (typically assumed to be 1) and c is the Gain Midpoint. The output of this function is intrinsically bound from 0.0 to 1.0 (exclusive).

In sub-step 42, the calculated factor is subtracted from 1, such that:
a. Signals with low amplitude at the Adaptation Level will have large gain factors (close to 1); and
b. Signals with high amplitude at the Adaptation Level will have minimal gain factors (close 0).

In sub-step 43, assuming the data contains a spatial component (such as an image would) the skewness of the signal distribution is calculated using traditional methods. If the spatial component is absent it can be derived from a long-term history of the element value over time. If this is not feasible, or desirable, an assumed value can be set for the Skew Coefficient, dependent on how Gaussian the data is assumed to be, which can be dependent on the sensor modality. For example, the skewness of electro-optical data is usually positive, whereas infra-red data can occupy a range of skewness values from positive to negative large and small depending on the environment and the lighting (time of day).

In sub-step 44, an absolute of the Skew Coefficient is taken to determine how large the difference between the gain extremes needs to be. At this sub-step, the polarity of the skewness is irrelevant, only the magnitude is used. As the absolute value of skewness decreases, the maximum gain decreases such that as skewness approaches 0 there will be less of a gain difference between high and low input values. This will result in an overall more Gaussian distribution than the input signal if the skewness magnitude is relatively high and no change if it is relatively low (e.g., the data is already close to Gaussian).

In sub-step 45, the absolute of the Skew Coefficient is then scaled by the maximum and minimum desired gain values for the model using Maximum Gain and Minimum. Gain parameters respectively. Typically, the minimum gain is almost always set to 1, while the maximum gain is selected to be approximately 20. However, this depends on the dynamic range of the incoming data. Where there is a very large difference between the expected maximum and minimum values seen across the sensor, and the dynamic range of the output of the model needs to be relatively small (i.e. more compression is required), then a larger maximum gain can be used.

In sub-step 46, the factors from the two pipelines are multiplied to create a single gain factor for the sample, where:
a. The factor from 41 and 42 is local, based on the sample's historical average relative to the Gain Midpoint; and
b. The factor from 43 and 44 is global, it considers overall bandwidth utilisation across all samples along any spatial dimensions.

In sub-step 47, the Minimum Gain is then added to the result, this ensures a minimum amount of gain is always applied to prevent setting samples to zero. Practically, this means the gainₘᵢₙᵢₘᵤₘ>0 and gainₘₐₓᵢₘᵤₘ>=gainₘᵢₙᵢₘᵤₘ.

In sub-step 48, lastly, the polarity of the Skew Coefficient is used to determine if step 40 will gain or attenuate the current signal. If the skewness is positive, the input is multiplied by the calculated gain such that low amplitude values are amplified, reducing the required dynamic range by raising the low end of the distribution. If the skewness is negative, the input signal is divided by the gain, such that low amplitude values of the distribution are further attenuated, redistributing the data values to be more Gaussian. This results in greater bandwidth utilisation of the signal regardless of the incoming data's distribution.

The third step 50 functions as a dynamic gamma correction via temporal adaptation. This achieves the two goals of shifting the signal distribution towards a more optimal Gaussian distribution and highlighting dynamic regions while suppressing static regions. The latter goal enables the model to intelligently compress signals, prioritising active (and thus interesting/salient) samples. This is done in three sub-steps.

In sub-step 51, the current sample is divided by a low pass filtered version of itself. As such:
a. Dynamic signals will have changes enhanced, while preserving polarity; and
b. Unchanging signals will approach a value of the square root of the input, suppressing them relative to dynamic samples.

The Divisive Time Constant controls the rate of adaptation, and thus the rate of suppression for static signals. In different embodiments, this value can be a constant or it can be dynamically adjusted based on the amount of dynamic activity expected or measured in the element. Highly dynamic elements, where novel elements are more desirable to capture, will want a relatively fast time constant to minimize any static elements and leave a larger proportion of the available signalling range free to encode the dynamic components of the data. Elements that have relatively slow changes may want a relatively low time constant so as not to supress all information within a scene as this will have the effect of reducing the contrast within the data.

In sub-step 52, the Divisive Power Offset and Divisive Power Factor parameters are used to calculate a power factor for sub-step 53. This factor is scaled using the Skew Coefficient from the second step 40. By taking the skew of the adapted data state into account, this step adaptively pushes data towards a Gaussian distribution to increase bandwidth utilisation.

In sub-step 53, a power function is applied, using the calculated power factor, creating a more Gaussian output distribution.

Much like the third step 50, the fourth step 60 acts as a dynamic gamma correction, but typically operates on a much longer timescale. The main difference between step 60 and the previous step 50 is that the rate of adaptation to a change in the input varies even more as a function of the difference between the current and historical (output of the low pass filter) values in step 60. This is achieved through the inclusion of an exponential operation in step 60.

Sub-step 61 functions as in sub-step 52, but with the inclusion of an exponential operation, and a fixed scale Exponent Sensitivity. The base of the exponential can vary depending on the importance of optimal processing speed (e.g., it can have a base of 2 or e, depending on which is faster to process for the model) and how fast the rate of adaptation needs to be. Relatively larger base and/or Exponent Sensitivity values will result in larger peak responses to changes at the input and shorter times to steady-state (i.e. a relatively faster adaptation).

Sub-step 62 functions identically to sub-step 52.

In sub-step 63, it is used to adaptively rescale the output signal to an expected range for the next processing step. This sub-step could be removed if the parameter Output Midpoint in the fifth step 70 was made adaptive since it would have the same affect.

The final and fifth step 70 in the model is a saturating non-linearity used to prepare the signal for output. It ensures that the signal exists within the desired bandwidth, usually a 0 to 1 range. Unlike the preceding four steps, this step includes no calculations for temporal adaptation, provided sub-step 63 is used. If sub-step 63 is not used, and the output of 60 is not scaled dynamically, then temporal adaptation of the Output Midpoint can be used.

In sub-step 71, a Naka-Rushton function

$$( \frac{{x}^{n}}{{x}^{n} + {c}^{n}} )$$

is applied where a midpoint or non-linear gain factor is supplied via Output Midpoint. The value of this midpoint is typically constant over all the data but can be variable based on the bandwidth utilisation (e.g., if the data is not taking up a sufficiently large range, c can be reduced to increase the data range without fear of exceeding the maximum range and causing hard clipping (saturation)). In most cases c is set at the median of the expected values at the input to this sub-step.

In sub-step 72, the Output Power Offset and Output Power Factor parameters are used to calculate a power factor for sub-step 73. This factor is scaled using the Skew Coefficient from sub-step 72. By taking the skew of the adapted image state into account, the model adaptively pushes the data towards a Gaussian distribution; thus improving bandwidth utilisation.

In sub-step 73, a final power operation is applied to the data. This is relatively less impactful than the one at the end of step 50, and thus is optional.

Those skilled in the art will also appreciate that the disclosure described herein is susceptible to variations and modifications other than those specifically described. It is to be understood that the disclosure includes all such variations and modifications.

The invention claimed is:

1-24. (canceled)

25: A computer-implemented data processing method to improve information quality in data sequences by attenuating noise in the data sequences, the method comprising:
receiving, from at least one sensor, input data sequences having a plurality of elements, wherein each of the elements has at least one dimensional component;
independently performing, by a processor, a spectral analysis on the at least one dimensional component of each of the elements to estimate a signal profile of the input data sequences;
estimating, by the processor, a noise profile of the input data sequences using calibration data associated with the at least one sensor;
dynamically calculating, by the processor, a time-constant for a noise attenuation filter, and adapting the time-constant over time, for each one of the elements in the input data sequences, based on a relationship between the noise profile and the signal profile;
applying, by the processor, the noise attenuation filter for each one of the elements to each respective one of the elements to filter the input data sequences to derive filtered data sequences; and
outputting the filtered data sequences.

26: The computer-implemented data processing method of claim 25, wherein for at least one of the plurality of elements, the at least one dimensional component of that element comprises a temporal component.

27: The computer-implemented data processing method of claim 26, wherein the at least one dimensional component further comprises a spatial component.

28: The computer-implemented data processing method of claim 25, wherein for at least one of the plurality of elements, the at least one dimensional component of that element comprises a temporal component derived from that at least one dimensional component.

29: The computer-implemented data processing method of claim 25, wherein the noise attenuation filter comprises a low-pass filter having the time-constant.

30: The computer-implemented data processing method of claim 25, further comprising estimating a signal-to-noise ratio of the input data sequences based on the relationship between the noise profile and the signal profile.

31: The computer-implemented data processing method of claim 30, further comprising:
comparing the signal-to-noise ratio to a minimum target signal-to-noise ratio, and
dynamically calculating the time-constant based on a result of the comparison of the signal-to-noise ratio and the minimum target signal-to-noise ratio.

32: The computer-implemented data processing method of claim 31, wherein the signal-to-noise ratio is compared to the minimum target signal-to-noise ratio by dividing the signal-to-noise ratio by the minimum target signal-to-noise ratio to obtain a filter value, and dynamically calculating the time-constant is based on the filter value such that a first filter value results in a first range of filtering and a second, greater filter value results in increasing amounts of filtering proportional to that filter value.

33: The computer-implemented data processing method of claim 32, wherein the time-constant has a maximum time-constant limit corresponding to a threshold filter value.

34: The computer-implemented data processing method of claim 30, further comprising:
dynamically calculating a further time-constant for a further noise attenuation filter based on a trend of the signal-to-noise ratio over time, and
applying the further noise attenuation filter to smooth the time-constant over time.

35: The computer-implemented data processing method of claim 34, wherein, responsive to the trend of the signal-to-noise ratio increasing over time, the further time-constant is decreased, and, responsive to the trend of the signal-to-noise ratio decreasing over time, the further time-constant is increased.

36: The computer-implemented data processing method of claim 35, wherein the further noise attenuation filter comprises a low-pass filter having the further time-constant.

37: The computer-implemented data processing method of claim 25, further comprising dynamically compressing a dynamic range of the filtered data sequences by applying an input gain to the filtered data sequences to derive corrected filtered data sequences.

38: The computer-implemented data processing method of claim 37, further comprising:
determining an adaptation level from the time-constant over time, and
determining the input gain using the adaptation level, wherein a first input gain is associated with first adaptation levels and a second, smaller input gain is associated with second, higher adaptation levels.

39: The computer-implemented data processing method of claim 38, further comprising:
estimating a skewness of the input data sequences by determining an amplitude modulation of the adaptation level across the input data sequences, and
determining a magnitude of the input gain based on the skewness.

40: The computer-implemented data processing method of claim 39, further comprising scaling the magnitude of the input gain between a minimum input gain and a maximum input gain.

41: The computer-implemented data processing method of claim 39, further comprising dynamically compressing the corrected filtered data sequences by applying a dynamic gamma correction having a gamma correction factor to the corrected filtered data sequences to derive compressed filtered data sequences.

42: The computer-implemented data processing method of claim 41, further comprising calculating the gamma correction factor based on the skewness.

43: The computer-implemented data processing method of claim 41, further comprising dynamically compressing the compressed filtered data sequences by applying a further dynamic gamma correction having a further gamma correction factor to the compressed filtered data sequences to derive further compressed filtered data sequences, wherein calculating the further gamma correction factor is based on the skewness.

44: The computer-implemented data processing method of claim 43, further comprising scaling the compressed filtered data sequences to a designated bandwidth to derive output data sequences by applying a designated gain based on a historical midpoint value of bandwidth usage of the compressed filtered data sequences.

45: The computer-implemented data processing method of claim 25, wherein the input data sequences are video data of any modality and the elements comprise pixels.

46: The computer-implemented data processing method of claim 25, wherein the input data sequences are video data of any modality and the elements comprise at least one of color and wavelength channels.

47: The computer-implemented data processing method of claim 25, wherein the input data sequences are audio data of any modality and the elements comprise at least one of spectrograms and frequency bands derived from the audio data.

48: The computer-implemented data processing method of claim 25, wherein the filtered data sequence has a non-uniform gain applied thereto.
